(19) United States
(12) Patent Application Publication
(10) Pub. No.: US 2016/0011233 A1
(43) Pub. Date: Jan. 14, 2016

(54) BRUSH SENSOR FOR MEASURING STATIC CHARGE OF FIBERS

(71) Applicant: The Procter & Gamble Company, Cincinnati, OH (US)

(72) Inventors: Haibo YUAN, Singapore (SG); Xiaozhong SHEN, Singapore (SG); Qian LI, Singapore (SG)

(21) Appl. No.: 14/796,242

(22) Filed: Jul. 10, 2015

Related U.S. Application Data
(60) Provisional application No. 62/023,957, filed on Jul. 14, 2014.

(51) Int. Cl. G01R 5/28; A46B 15/00

(52) U.S. Cl. CPC G01R 5/28; A46B 15/0002

(57) ABSTRACT

Disclosed herein is a sensor for measuring static charge of fibers, comprising: a sensor handle which is insulated; a metal sensor head connecting to the sensor handle; an electrometer and a capacitor, both inside of the sensor handle; and a display on the handle, and wherein the static charge generated during a contact between the fiber and the sensor head is transferred from the sensor head to the capacitor, measured by the electrometer connected to the capacitor, and shown on the display. The sensor head is preferably in the shape of a brush or comb, and the static charge is generated during combing.

### FIELD OF THE INVENTION

The present invention relates a sensor for measuring static charge of fibers, comprising: a sensor handle which is insulated; a metal sensor head connecting to the sensor handle; an electrometer and a capacitor, both inside of the sensor handle; and a display on the handle, and wherein the static charge generated during a contact between the fiber and the sensor head is transferred from the sensor head to the capacitor, measured by the electrometer connected to the capacitor, and shown on the display. The sensor head is preferably in the shape of a brush or comb, and the static charge is generated during combing.

### BACKGROUND OF THE INVENTION

Keratinaceous fibers, particularly human hair fibers, may be damaged over time. Damages may be caused by environmental factors, including air pollution, sun exposure, chlorine from water pool, and/or rain. Damages may also be caused by applying to the fibers grooming (cosmetic), chemical and/or mechanical treatments. When hair fibers are damaged, the hair fibers may have undesirable conditions of, for example, “fly-away hair”, “split end”, and/or color fade.

Assessing the condition including the degree of damages caused to keratinaceous fibers is of interest in order to understand the impact of various environmental factors as well as the impact of the cosmetic (grooming), chemical and mechanical treatments onto keratinaceous fibers. Such assessment is also of interest in order to demonstrate the efficacy of treatments used for preventing and/or repairing keratinaceous fiber damages. Several attempts for assessing keratinaceous fiber damages, using different methods and/or devices, have already been reported.

Measuring electrostatics of fibers, especially when combing fibers is one of common ways to assess keratinaceous fiber conditions. Generally speaking, more electrostatics on fibers cause more fly-away of fibers. More damaged and/or curled keratinaceous fibers may cause more electrostatics when combing because of more friction and/or detangling between fibers when combing.

For example, an article “The electrostatic properties of human hair” published in J. Soc. Cosm. Chem., 28, 549-569, in 1977, discloses a measurement of electrostatic changes generated on hair tress by combing, in a faraday cage connecting to electrometer.

However, there still remains a need for providing an electrostatic measurement device which is easy to use.

### SUMMARY OF THE INVENTION

The present invention is directed to a sensor for measuring static charge of fibers, comprising:

a sensor handle which is insulated;

a metal sensor head connecting to the sensor handle;

an electrometer and a capacitor, both inside of the sensor handle; and

a display on the sensor handle;

and wherein the static charge generated during a contact between the fiber and the sensor head is transferred from the sensor head to the capacitor, measured by the electrometer connected to the capacitor, and shown on the display.

This sensor does not require a faraday cage for static charge measurements, and is easy to use compared to the one requiring such a faraday cage.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the invention.

FIG. 1 illustrates an example of a mechanism inside of the sensor handle and its connection to a metal sensor head in a comb shape and display.

### DETAILED DESCRIPTION

While the specification concludes with claims that particularly point out and distinctly claim the invention, it is believed the present invention will be better understood from the following description.

### Sensor

The sensor of the present invention is for measuring static charge of fibers, comprising:

a sensor handle which is insulated;
a metal sensor head connecting to the sensor handle;
an electrometer and a capacitor, both inside of the sensor handle; and
a display on the sensor handle;
and wherein the static charge generated during a contact between the fiber and the sensor head is transferred from the sensor head to the capacitor, measured by the electrometer connected to the capacitor, and shown on the display.

The sensor head can be in a shape of a comb, brush, rod, or clamp. Preferably, the sensor head is in a shape of a comb or brush, and the static charge is generated during combing.

When the sensor head is in the shape of a comb or brush, the sensor head usually have teeth. The gap between such teeth can be about 1-5 mm, and the length of the comb sensor head (the distance between the first tooth to the final tooth, wherein the first tooth is located at the near end of the comb sensor head from the handle, and the final tooth is located at the far end of the comb sensor head from the handle) can be about 50-100 mm, and the width of the comb sensor head (which is almost equal to the length of the teeth) can be about 20-40 mm

The sensor handle is insulated by any known means, for example, plastics and rubber. The metal used in the sensor head can be also anything as long as it meets the objective of the present invention, for example, aluminum, steel, copper, and brass.

The metal sensor head can be made by a metal only, or can be made by plastics with a metal coating.

### Display

The sensor of the present invention comprises a display to show the static charge measured by the electrometer.

The static charge shown in the display can be a static charge per se, a static charge difference between a first static charge and a second static charge, or a fiber condition which is assessed by the static charge. Such fiber conditions are, for example, damage, smoothness and/or moisture level.

The display can show such static charges (static charge per se, static charge difference between a first static charge and a second static charge, or fiber conditions) one by one, or all concurrently.

The static charge per se and static charge differences can be shown by absolute values, relative values and/or indexes.

When the display can show a static charge difference between a first static charge and a second static charge, it is preferred that the sensor also show the first static charge per se; the second static charge per se.

Data storage and Calculator

Preferably, the sensor further comprises a data storage which can memorize at least two different static charges. Preferably, the sensor further comprises a calculator which can calculate a difference between a first static charge and a second static charge.

Preferably, the data storage and calculator are located in the sensor handle. Alternatively, the data storage and calculator can be located separately from the sensor, and are located, for example, in PC and/or cellular phone which has a wireless connection with the sensor. In another example, the data storage and calculator can be located in both in the sensor handle and in separate PC and/or cellular phone which has a wireless connection with the sensor.

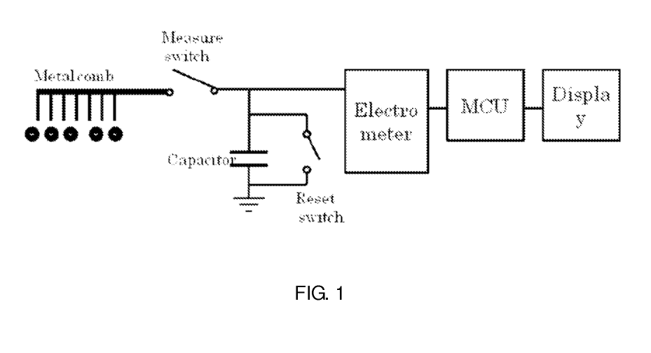

The data storage and calculator can be combined. For example, as shown in FIG. 1, MCU (Micro Controller Unit) can serve as both of the data storage and calculator.

### Discharging Function

Preferably, the sensor further comprises a discharging function which enables the discharge of the static charge of the sensor. The discharging function is preferably located inside of the sensor handle. For this discharging function, it is preferred that at least one part of the sensor handle is made by a metal or coated by a metal which has an electrical connection to the capacitor at least upon the activation of the discharging function. This metal part is preferably located at a position on the handle which is almost automatically touched by operators when activating the discharging function. More preferably, this metal part can be an activation button.

### Activation Button

Preferably, the sensor further comprises an activation button on the sensor handle which activates at least one selected from the group consisting of: the display of the static charge; the discharging function; and combinations thereof. The activation button can activate other functions as well. Such other functions are, for example, data storage, calculation.

Such activation can be done by pushing the button by order, for example, first push enables the display, and then the second push enables the discharging. Alternatively, such activation can be done by sliding the button to a certain position according to the indication of a certain function.

### Additional Functions

The sensor of the present invention can also contain a humidity sensor, temperature sensor, or the combination thereof. The data obtained by these additional sensors can be used for adjusting measurement result of the static charge of the fibers.

The sensor of the present invention can also contain an ionic function which can emit minus ion from the sensor to the fibers, and can neutralize the fiber especially after combing and/or measurement.

### One Preferred Embodiment

In one preferred embodiment, the sensor of the present invention is for measuring static charge of fibers, comprising:

a sensor handle which is insulated;
a metal comb sensor head connecting to the handle and having teeth;
an electrometer, a capacitor, a data storage, a calculator, and discharging function, all inside of the handle;
a display on the handle; and
an activation button on the handle which activates at least one selected from the group consisting of: the display of the static charge; the discharging function; and combinations thereof. and wherein the static charge generated during combing is transferred from the sensor head to the capacitor, measured by the electrometer connected to the capacitor, and shown on the display.

FIG. 1 illustrates an example of a mechanism inside of the sensor handle and its connection to the metal comb sensor head and display, in the above preferred embodiment.

In this example, MCU serve as the data storage and calculator. While it's not illustrated in FIG. 1, the activation button connects to the MCU, and activates several functions such as display and discharging through MCU.

In this example, static charge generated during combing is transferred from the sensor head to the capacitor upon the activation of the measure switch by the activation button through MCU, and measured by the electrometer. The static charge is shown on the display through MCU, and preferably recorded in the MCU. Then the reset switch is activated by the activation button through MCU.

The measure switch and resent switch herein are preferably both electrical. Alternatively the measure switch and resent switch can be mechanical in another embodiment. In such case, activation button can connect directly them without the intervention of MCU.

### Fiber

As used herein, “fiber” means any fiber, and preferably that can be influenced by any of the cosmetic, chemical and/or mechanical treatments. Said fiber is preferably a mammal hair, more preferably a human hair including a synthetic fibers made like a human hair (hereinafter “synthetic hair”). The origin of the human hair may be Caucasian, African, Asian, or any other origin. The hair fiber may be obtained from any part of the body, e.g. the legs, the arms, the torso, the face or the scalp. The hair fiber is preferably obtained from the scalp.

When the fibers are mammal hair, the method of the present invention can be done in vivo, using mammal hairs as hair samples without cutting. Alternatively, the method of the present invention can be done in-vitro.

Fiber samples may comprise from about 100 fibers to about 300,000 fibers, preferably from about 500 fibers to about 150,000 fibers, more preferably from about 1,000 fibers to about 50,000 fibers. Said fiber samples may be bundled to each other such that the bundle has at least one free end. One sample usually comprises fibers of the same origin (e.g. from the same person and the same region of the body), and/or of the same portion (e.g. root end or tip end of hair fibers), and/or having been subjected to the same cosmetic, chemical and/or mechanical treatments. When providing at least two, preferably from two to four, more preferably two, different samples of keratinaceous fiber(s), “different samples” means samples differing from each other by the origin of the fibers, the portion of the fibers and/or the treatment(s) applied to fibers.

The fibers may be of sufficient length for the method of the present invention. The fibers have preferably a length of 1 cm to 80 cm, more preferably of 10 cm to 50 cm, still more preferably of 20 cm to 30 cm. When fibers are bundled to each other, it is preferred that the fibers have the above length from the point to be bundled.

### Treatment

The fiber samples may be treated by any suitable cosmetic composition, chemical and/or mechanical treatment. The treatment may be carried out before the sample provision. The treatment can be carried out before or after the sample provision, and is preferably carried out before the measurement.

This treatment may be carried out by applying a cosmetic composition onto keratinaceous fiber. Any suitable cosmetic composition known in the art may be used such as shampoos, conditioning compositions, hair rinse-off treatments, hair leave-on treatments, styling compositions. For example, any commercially available shampoos, conditioners, hair rinse-off treatments and hair leave-on treatments of tradename Pantene® and Head & Shoulders® may be used.

Only one composition may be applied onto fibers. Alternatively, two or several compositions may be applied simultaneously or sequentially. In addition, before and/or after applying each composition, the fibers may further be wetted, rinsed and/or dried. In one embodiment, the treating step comprises treating (washing) the fibers with a shampoo, then rinsing the washed fibers with water, then drying the fibers. In another embodiment, the treating step comprises treating (washing) the fibers with a shampoo, then rinsing the washed fibers with water, then treating the fibers with a conditioning composition, then rinsing the treated fibers with water, then drying the fibers. In another embodiment, the treating step comprises treating (washing) the fibers with a shampoo, then rinsing the washed fibers with water, then treating the fibers with a conditioning composition, then rinsing the treated fibers with water, then treating at least one time the fibers with a hair rinse-off treatment, then rinsing the treated fibers with water, then drying the fibers.

Alternatively or complementary, this step may be carried out by chemically treating the fibers using a chemical treatment. Any suitable chemical treatment known in the art may be used such as permanent waving treatment, bleaching treatment and/or color-dyeing treatment.

Alternatively or complementary, this step may be carried out by mechanically treating the fibers. Any suitable mechanical treatment known in the art may be used such as brushing, combing, towel rubbing, and/or blow drying.

### Static Charge Measurement and Comparison

The sensor of the present invention is used for measuring static charge generated during a contact between the sensor and a fiber sample, preferably, during combing a fiber sample.

The static charges of different fiber samples may be compared by, for example, showing a difference of the static charges.

The comparison is beneficial for comparing the effects of one treatment onto fibers versus no treatment. In one embodiment, one sample may comprise untreated fibers and the other sample comprises fibers treated with a cosmetic composition. The other sample may be treated with a shampoo, and/or a conditioning composition, and/or a hair rinse-off treatment, and/or a leave-on treatment, and/or any other suitable cosmetic composition. Comparing treated fiber(s) and untreated fiber(s) is beneficial for assessing the damaging effects of the compositions such as shampoos onto hair or, in contrast, for assessing the benefits of the compositions such as conditioning compositions. Such benefit can be, for example: reduction of static charge, detangling and/or friction of fibers; prevention of increase of static charge, detangling and/or friction of fibers; reduction, prevention and/or repair of damages of fibers; increase and/or improve of smoothness and/or moisture level of fibers.

The comparison is further beneficial for comparing the efficacy of at least two different treatments. Such efficacy can be, for example: reduction of static charge, detangling and/or friction of fibers; prevention of increase of static charge, detangling and/or friction of fibers; reduction, prevention and/or repair of damages of fibers; increase and/or improve of smoothness and/or moisture level of fibers.

In one embodiment, the samples may be treated with different cosmetic compositions. For example and non-exhaustively, (1) one sample may be treated with one shampoo and the other sample with another shampoo; (2) one sample may be treated with one shampoo and the other sample may be treated with the same shampoo and then one conditioner; (3) one sample may be treated with one shampoo and then one conditioner and the other sample may be treated with the same shampoo and then another conditioner, (4) one sample may be treated with one shampoo and then one conditioner and the other sample may be treated with the same shampoo, then the same conditioner, and then a rinse-off treatment, (5) one sample may be treated with one shampoo and then one conditioner and the other sample may be treated with the same shampoo, then the same conditioner, and then a leave-on treatment, (6) one sample may be treated with one shampoo and then one conditioner and the other sample may be treated with another shampoo and then the same conditioner; (7) one sample may be treated one time with one shampoo and the other sample may be treated two or several time with the same shampoo; (8) one sample may be treated one time with one conditioner and the other sample may be treated two or several times with the same conditioner. Comparing differently treated fiber(s) is beneficial for comparing the damaging effects of different shampoos (see (1)); for assessing the mitigating effects of conditioners onto shampoo treatments (see (2)); for comparing the benefits of conditioning compositions (see (3)); for assessing the mitigating effects of rinse-off treatments onto shampoo treatments (see (4)); for assessing the mitigating effects of leave-on treatments onto shampoo treatments (see (5)); for comparing the mitigating effects of one conditioners onto different shampoo treatments (see (6)); for comparing the effects of repeating treatments onto fiber(s) (see (7) and (8)).

The comparison is beneficial for example for comparing the effects of chemical and/or mechanical treatments. For example, in one embodiment, one sample may comprise untreated fiber(s) and the other sample comprises fibers being chemically-treated. Alternatively, the samples may comprise fiber(s) be treated with different chemical treatments. In another embodiment, one sample may comprise untreated fiber(s) and the other sample comprises fibers being mechanically-treated. Alternatively, the samples may comprise fiber(s) be treated with different mechanical treatments.

The comparison between two different samples may be used for supporting advertising claims, for example, for advertising the efficacy of a treatment and/or for advertising the superiority of one treatment versus another treatment. Such efficacy can be, for example: reduction of static charge, detangling and/or friction of fibers; prevention of increase of static charge, detangling and/or friction of fibers; reduction, prevention and/or repair of damages of fibers; increase and/or improve of smoothness and/or moisture level of fibers.

When advertising one treatment (e.g. a conditioning composition) versus another one, the data and/or the pictures obtained using this method may be used therefore support and/or demonstrate advertising claims according to which said treatment provide higher performance versus the other one.

### EXAMPLE

### Materials

Sample: About 30 cm long, a bundle of 10 g Virgin-oriental hair fibers
Sensor: having a mechanism inside of the sensor handle and its connection to the metal comb sensor head and display as shown in FIG. 1, and comprising:
a sensor handle which is insulated;
an aluminum comb sensor head connecting to the sensor handle and having teeth;
an electrometer, a capacitor, MCU serving as a data storage and a calculator, and discharging function, all inside of the handle,
a display on the handle; and
an metal activation button on the handle and connecting to MCU inside of the handle, which activates several functions such as display and discharging through MCU.

The gap between each teeth is about 1-5 mm, and the length of the comb sensor head (the distance between the first tooth to the final tooth, wherein the first tooth is located at the near end of the comb sensor head from the handle, and the final tooth is located at the far end of the comb sensor head from the handle) can be about 50-100 mm, and the width of the comb sensor head (which is almost equal to the length of the teeth) can be about 20-40 mm

Non-conditioning shampoo composition: having pH=5-7 and comprising Ammonium laureth-3 sulfate (12.8%), Ammonium lauryl sulfate (9.1%), Cocamide DEA (2.3%), Ammonium xylenesulfonate (1%), EDTA (0.1%), Preservatives (<1%), Water q.s. to 100%.

Conditioning shampoo composition : having pH=5-7, and comprising Sodium laureth-3 sulfate (8.5%), Sodium lauryl sulfate (1.7%), Cocamidopropyl betaine (1.7%), Sodium lauroamphoacetate (1.7%), Cocamide MEA (0.85%), Glycol Disterate (1.5%), Polyquaternium-10 (0.4%), Dimethicone (1%), Preservatives (0.6%), Water q.s. to 100%.

Conditioning composition: having pH=5-7, and comprising Behentrimonium methosulfate (2.2%), Fatty alcohols (3.8%), Aminodimethicone (1.5%), Preservatives (0.6%), Water q.s. to 100%.

Percentages of compounds are weight percent per total weight of the composition

### Protocol

Depending on the method carried out, some of the steps may be omitted, e.g. shampoo and/or conditioning steps.

1. [Sample provision step for Samples A and B] Preparing the above hair sample.
2. [Shampoo step for Samples A and B]:

2.1 Hang a sample on bar

2.2 Wet the sample

2.3 Apply 1 ml of Non-conditioning shampoo composition to the sample and lather for 30 seconds

2.4 Rinse the sample for 30 seconds

2.5 Repeat 2.3 and 2.4

2.6 Rinse the sample for 120 seconds and squeeze the sample to remove excess water

2.7 Dry the sample for 24 hours.

3. [Conditioning Shampoo step for Samples A only]:

3.1 Hang a sample on bar

3.2 Wet the sample

3.3 Apply 1 ml of Non-conditioning shampoo composition to the sample and lather for 30 seconds

3.4 Rinse the sample for 30 seconds

3.5 Repeat 2.3 and 2.4

3.6 Rinse the sample for 120 seconds and squeeze the sample to remove excess water

4. [Conditioning step for Sample A only]

4.1 Hang a sample on bar

4.2 Apply 1 ml of Conditioning composition to the sample and milk for 30 seconds

4.3 Rinse the sample for 30 seconds and squeeze the sample to remove excess water

4.4 Pat-towel-dry the sample and comb once

4.5 Dry the sample for 24 hours

5. [Measuring step for Samples A and B] Measuring the static charge of the hair sample by using the above brush at about 40% of relative humidity. In more detail, static charge generated during combing is transferred from the metal comb head to the capacitor upon the activation of the measure switch by the activation button through MCU, and measured by the electrometer. The static charge is shown on the display through MCU, and recorded in the MCU. Then the reset switch served as the discharging function is activated by the activation button through MCU. Then the sensor becomes ready for another measurement.
6. [Comparison step] Comparing the static charges of two different samples.

### Comparison of Static Charges

According to the above materials and protocols, two samples are provided with different treatments as shown in Table 1, and static charges generated during combing are measured by the above brush sensor. The measurement results are shown below in Table 1.

TABLE 1

| | | Static charge shown |
|---|---|---|
| Samples | Treatments | on the display |
| A | Shampoo + Conditioning Shampoo + | About 89 |
| | Conditioning | |
| B | Shampoo only | About 111 |

As shown in Table 1, the static charge of Sample A is much lower than that of Sample B. This also shows the efficacy of Conditioning shampoo and/or Conditioning composition, which were used in only for Sample A.

The dimensions and values disclosed herein are not to be understood as being strictly limited to the exact numerical values recited. Instead, unless otherwise specified, each such dimension is intended to mean both the recited value and a functionally equivalent range surrounding that value. For example, a dimension disclosed as “40 mm” is intended to mean “about 40 mm.”

All documents cited in the Detailed Description of the Invention are, in relevant part, incorporated herein by reference; the citation of any document is not to be construed as an admission that it is prior art with respect to the present invention.

While particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention.

What is claimed is:

1. A sensor for measuring static charge of fibers, comprising:
a sensor handle which is insulated;
a metal sensor head connecting to the sensor handle;
an electrometer and a capacitor, both inside of the sensor handle, and
a display on the sensor handle;
and wherein the static charge generated during a contact between the fiber and the sensor head is transferred from the sensor head to the capacitor, measured by the electrometer connected to the capacitor, and shown on the display.

2. The sensor of claim 1 wherein the sensor head is in a shape of a comb, brush, rod, or clamp.

3. The sensor of claim 1 wherein the sensor head is in a shape of a comb or brush, and the static charge is generated during combing.

4. The sensor of claim 1, wherein the sensor further comprises a discharging function which enables the discharge of the static charge of the sensor.

5. The sensor of claim 1, wherein the static charge shown in the display is a static charge difference between a first static charge and a second static charge.

6. The sensor of claim 1, wherein the sensor further comprises a data storage which can memorize at least two different static charges.

7. The sensor of claim 6, wherein the data storage is in the sensor handle.

8. The sensor of claim 1, wherein the sensor further comprises a calculator which can calculate a difference between the first static charge and the second static charge.

9. The sensor of claim 8, wherein the calculator is in the sensor handle.

10. The sensor of claim 1, wherein the sensor further comprises an activation button on the sensor handle which activates at least one selected from the group consisting of: the display of the static charge; the discharging function; and combinations thereof.
